(19) United States
(12) Patent Application Publication
(10) Pub. No.: US 2013/0316074 A1
(43) Pub. Date: Nov. 28, 2013

(54) Manufacturing method of a retaining wall of an LED

(71) Applicants: YoungKi Kim, Suwon (KR); DongMyung Kim, Suwon (KR); ChungSeok Lee, Suwon (KR); Gil Mo Nam, Suwon (KR); JongSoo Ha, Suwon (KR)

(72) Inventors: YoungKi Kim, Suwon (KR); DongMyung Kim, Suwon (KR); ChungSeok Lee, Suwon (KR); Gil Mo Nam, Suwon (KR); JongSoo Ha, Suwon (KR)

(73) Assignees: AAC TECHNOLOGIES HOLDINGS INC., CAYMAN ISLANDS (GB); AAC ACOUSTIC TECHNOLOGIES (SHENZHEN) CO., LTD, Shenzhen (CN)

(21) Appl. No.: 13/902,711

(22) Filed: May 24, 2013

(30) Foreign Application Priority Data
May 25, 2012 (CN) 201210166751.1

(51) Int. Cl. H01L 33/00

(52) U.S. Cl. CPC H01L 33/005
USPC 427/64; 427/126.2

(57) ABSTRACT

A manufacturing method of a retaining wall of an LED, the method includes the steps of: step A, providing a ceramic substrate; providing a printing screen; providing ceramic slurry including thermal curing agent; step B, forming multiple pairs of electrodes on the ceramic substrate; depositing the ceramic slurry on the ceramic substrate by the printing screen for forming a first ceramic layer around each pair of electrodes; step C, drying the first ceramic layer for twenty to thirty minutes under a temperature between 100 to 150 centigrade for hardening the first ceramic layer; step D, depositing the ceramic slurry on the first ceramic layer for forming a second ceramic layer by the printing screen, and then hardening the second ceramic layer; step E, repeating step D for forming a third ceramic layer for forming the retaining wall.

### FIELD OF THE INVENTION

The present invention relates to the art of LED (Light Emitting Diode), more particularly to a manufacturing method of a retaining wall of an LED used in a portable electric product.

### BACKGROUND OF THE INVENTION

With the quick development of electric products, more especially, the portable electric products, such as cellphone, notebook etc., people have stronger requirements for the functions not only of the acoustic performance of communication, but also of the optical performance of the camera. Thereby, LED lens equipped with the portable electronic devices for providing photographic functions are more and more used.

A related LED lens generally comprises a substrate, an LED unit disposed on the substrate, and a lens unit for packaging the LED unit.

However, the cost of the lens unit is high as the Lens unit manufactured by die casting. For solving the problem of high cost, another packaging method following the process sequence “printing-drying-printing” is used to form a retaining wall by screen printing. In this packaging method, simple drying process is used to form the retaining wall by drying the printing materials, which leads the retaining wall to deform due to the pressure from the printing screen during reduplicate printing processes. If the retaining wall needs to reach 150 um high, at least ten times of printing processes should be applied, which may seriously lower the efficiency of the packaging process.

In view of above, a new manufacturing method of a retaining wall of an LED is disclosed to solve the above mentioned problems.

### BRIEF DESCRIPTION OF THE DRAWINGS

The foregoing advantages of the invention will be appreciated more fully from the following further description thereof with reference to the accompanying drawings wherein:

FIGS. 1a-1d indicate a flow schematic diagram of a manufacturing method of a retaining wall of an LED according to an embodiment of the present invention;

FIG. 2 is a partial structural isometric view of the LED according to the embodiment of the present invention.

### DESCRIPTION OF ILLUSTRATIVE EMBODIMENTS

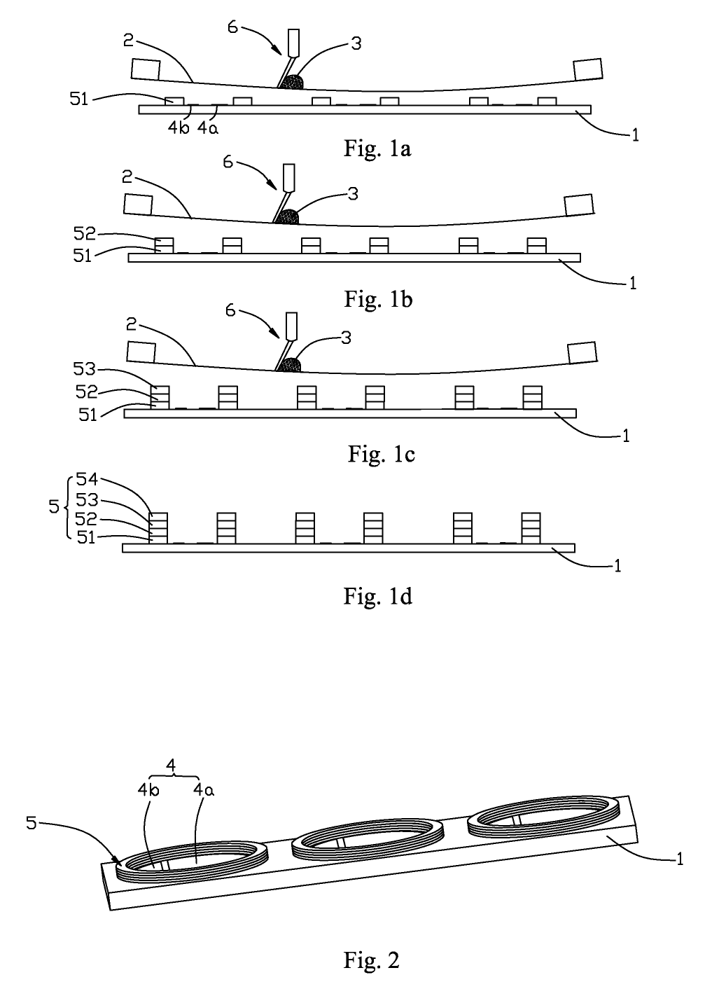

As shown in FIGS. 1-2, a manufacturing method of a retaining wall of an LED (Light Emitting Diode), comprises the following steps:

step A:

providing a ceramic substrate 1;

providing a printing screen 2;

providing ceramic slurry 3, the ceramic slurry 3 including thermal curing agent;

step B:

as shown in FIG. 1a, forming multiple pairs of electrodes 4 including positive electrodes 4a and negative electrodes 4b, on the ceramic substrate 1 for electrically connecting with the LED; depositing the ceramic slurry 3 on the printing screen 2 for forming a first ceramic layer 51 around each pair of electrodes 4 by a printing unit 6; wherein in the embodiment of the present invention, the electrodes 4 are formed on the ceramic substrate 1 by silver plating, and in alternative embodiments, the electrodes 4 may be formed by other available methods, such as by printed circuit boards (PCB), flexible printed circuit broads (FPCB), plating copper lines, and so on.

step C, drying the first ceramic layer 51 for a certain time, for example twenty to thirty minutes, under a temperature between 100 to 150 centigrade for hardening the first ceramic layer 51;

step D, as shown in FIG. 1b, forming a second ceramic layer 52 by depositing the ceramic slurry 3 on the first ceramic layer 51 using the printing screen 2, and then hardening the second ceramic layer 52, like step C;

step E, as shown in FIGS. 1c and 1d, forming a third ceramic layer 53 and a fourth ceramic layer 54 following the process in Step D; the first, second, third, and fourth ceramic layers 51, 52, 53, 54 cooperatively form a retaining wall 5 of the LED.

In the manufacturing method of the retaining wall of the LED of the present invention, since the ceramic slurry 3 comprises thermal curing agent, the ceramic slurry 3 may be more easily hardened and can provide higher hardness. As a result, when a new hardened ceramic layer is formed on an existed ceramic layer, the undesired deformation of the existed ceramic layer by the pressure of the printing screen could be avoided. Therefore, the manufacturing method of the retaining wall 5 disclosed in the present invention greatly reduces the times of screen printing, and improves the production efficiency. Meanwhile, in traditional manufacturing method, the retaining wall reaches 150 um high, which needs repeating the screen printing more than ten times. However, in the present invention, for the same height, it only needs repeating the screen printing three to four times.

Optionally, the ceramic slurry 3 comprises 60-80 percent inorganic matters and 20-40 percent organic matters. The inorganic matters comprise white glass-ceramic and the organic matters comprise epoxy resin, dispersant agent and thermal curing agent of amine series.

In the embodiment, each of the ceramic layers is formed by “printing-drying-printing” process, and each ceramic layer is provided with a higher hardness after being hardened by the ceramic slurry 3 including thermal curing agent. Therefore, the thickness of each ceramic layer is the same.

Optionally, inside of the retaining wall 5 is coated by phosphrescent material. Due to the same thickness of each ceramic layer, the phosphrescent material could be coated inside of the retaining wall uniformly, which further improves the reflectivity of the retaining wall 5 for increasing heat transfer and luminous efficiency. Therefore, the reliability of the LED is improved.

Compared with the traditional technology, the manufacturing method of the present invention is quite simple and can greatly reduce the process steps of screen printing for improving the production efficiency. The retaining wall is formed by white ceramic slurry and inside of the retaining wall is coated by phosphorescence material, which can further improve reflectivity of the retaining wall 5 for increasing heat transfer and luminous efficiency. Therefore, the reliability of the LED can be improved.

Although the above discussion discloses various exemplary embodiments of the invention, it should be apparent that those skilled in the art can make various modifications that will achieve some of the advantages of the invention without departing from the true scope of the invention.

What is claimed is:

1. A manufacturing method of a retaining wall of a light emitting diode, comprising the steps of:
step A, providing a ceramic substrate;
providing a printing screen;
providing ceramic slurry including thermal curing agent;
step B, forming multiple pairs of electrodes on the ceramic substrate;
depositing the ceramic slurry on the ceramic substrate by the printing screen for forming a first ceramic layer around each pair of electrodes;
step C, drying the first ceramic layer for twenty to thirty minutes under a temperature between 100 to 150 centigrade for hardening the first ceramic layer;
step D, depositing the ceramic slurry on the first ceramic layer for forming a second ceramic layer by the printing screen, and then hardening the second ceramic layer;
step E, repeating step D for forming a third ceramic layer for forming the retaining wall.

2. The manufacturing method of claim 1, wherein, the ceramic slurry comprises 60-80 percent inorganic matters and 20-40 organic matters.

3. The manufacturing method of claim 2, wherein the inorganic matters comprise white glass-ceramic and the organic matters comprise epoxy resin, dispersant agent and thermal curing agent of amine series.

4. The manufacturing method of claim 1, wherein, the thickness of each ceramic layer is the same.

5. The manufacturing method of claim 1, wherein, inside of the retaining wall is coated by phosphorescence material.
